(19) United States
(12) Patent Application Publication
(10) Pub. No.: US 2008/0304238 A1
(43) Pub. Date: Dec. 11, 2008

(54) ELECTRONIC DEVICE HAVING PASSIVE HEAT-DISSIPATING MECHANISM

(75) Inventors: Shih-Kai Chien, Taoyuan (TW); Yin-Yuan Chen, Taoyuan (TW); Ke-Cheng Lin, Taoyuan (TW); Jui-Yuan Hsu, Taoyuan (TW); Wen-Yi Yeh, Taoyuan (TW)

Correspondence Address: MADSON & AUSTIN, 15 WEST SOUTH TEMPLE, SUITE 900, SALT LAKE CITY, UT, 84101, US

(73) Assignee: Delta Electronics, Inc., Taoyuan (TW)

(21) Appl. No.: 11/938,590

(22) Filed: Nov. 12, 2007

(30) Foreign Application Priority Data
Jun. 6, 2007 (TW) 096120398

(51) Int. Cl. H05K 7/20

(52) U.S. Cl. 361/705; 361/709

(57) ABSTRACT

The present invention relates to an electronic device having a passive heat-dissipating mechanism. The electronic device includes a circuit board and a radiation enhancement layer. The circuit board has at least an electronic component thereon. The radiation enhancement layer is attached onto at least a portion of a surface of the electronic component for facilitating radiating the heat from the electronic component to the ambient air via natural convection. The radiation enhancement layer is made of a ceramic material.

### FIELD OF THE INVENTION

The present invention relates to an electronic device, and more particularly to an electronic device having a passive heat-dissipating mechanism.

### BACKGROUND OF THE INVENTION

With increasing integration of integrated circuits, electronic devices such as power adapters and power supply apparatuses are developed toward minimization. As the volume of the electronic device is decreased, the problem associated with heat dissipation becomes more serious. Take a power adapter for example. The conventional power adapter comprises an upper housing and a lower housing, which are made of plastic materials and cooperatively defines a receptacle for accommodating a circuit board therein. When the power adapter operates, the electronic components on the printed circuit board thereof may generate energy in the form of heat, which is readily accumulated within the receptacle and usually difficult to dissipate away. If the power adapter fails to transfer enough heat to ambient air, the elevated operating temperature may result in damage of the electronic components, a breakdown of the whole power adapter or reduced power conversion efficiency.

Referring to FIG. 1, a schematic cross-sectional view of a conventional power adapter having a passive heat-dissipating mechanism is illustrated. The power adapter 1 comprises an upper housing 11, a lower housing 12, a printed circuit board 13, a power input terminal (not shown) and a power output terminal 14. A receptacle is defined between the upper housing 11 and the lower housing 12 for accommodating the printed circuit board 13 therein. Many electronic components 131 and electrical trace patterns (not shown) are mounted on the printed circuit board 13. By the electronic components 131 and the electrical trace patterns, an input voltage from the external power source is converted into a regulated DC output voltage for powering an electronic product. In order to remove most heat generated from the electronic components 131, several heat sinks 132 are usually provided on the printed circuit board 13. In addition, some electronic components 131 are coupled to the heat sinks 132 by screwing, clamping or riveting connection, thereby facilitating heat dissipation.

The passive heat-dissipating mechanism of the power adapter 1 comprises conducting the heat generated from the electronic components 131 to the heat sinks 132, radiating the heat from the surfaces of the heat sinks 132 to the receptacle of the power adapter 1, transferring the heat from the receptacle to the upper housing 11 and the lower housing 12 through air, and afterwards performing heat-exchange with the surrounding of the power adapter 1. Since the power adapter is developed toward minimization and designed to have higher power, the passive heat-dissipating mechanism described above is not satisfactory.

Recently, planar displays such as liquid crystal displays (LCD) became indispensable to our lives. A liquid crystal display usually has a power supply apparatus for offering the required operating power. When the power supply apparatus operates, the electronic components on the printed circuit board thereof may generate energy in the form of heat, which is readily accumulated around the circuit board and difficult to dissipate away. If the power supply apparatus fails to transfer enough heat to the ambient air, the elevated operating temperature may result in damage of the electronic components, a breakdown of the whole power supply apparatus or reduced operation efficiency. Therefore, it is important to dissipate the heat generated from the electronic components in order to stabilize the operation and extend the operational life.

Since the planar display is developed toward minimization, the electronic device with the large fan fails to meet the requirement of small size, light weightiness and easy portability. In other words, the large fan should be exempted from the planar display and thus natural convection may be taken into consideration. That is, the heat generated from the electronic components on the circuit board is dissipated to the ambient air by conduction, convection and radiation. Referring to FIG. 2, a heat-dissipating mechanism for removing the heat generated from the electronic components via natural convection is illustrated. The heat-dissipating device of FIG. 2 is for example applied to a power supply apparatus 2 of a liquid crystal display. As shown in FIG. 2, several electronic components 22, 23 and 24 are mounted on a circuit board 21 of the power supply apparatus 2. These electronic components 22, 23 and 24 are contacted with or separated from the heat sink 25. For example, the electronic component 22 is screwed onto the heat sink 25, and the electronic components 23 and 24 are arranged in the vicinity of the heat sink 25. The heat generated from the electronic component 22 during operation will be conducted to the heat sink 25, spread over the surface of the heat sink 25, and transferred from the surface of the heat sink 25 to the ambient air via radiation and natural convection. Whereas, the heat generated from the electronic component 23 or 24 is directly transferred to the ambient air via radiation and natural convection.

Generally, the heat-dissipating efficiency of the power adapter or the power supply apparatus for the liquid crystal display is mainly dependent on the capability of radiating heat. If a hot object at a temperature T₁(K) is radiating energy to its cooler ambient air at temperature T₂ (K), the Stefan-Boltzmann equation is expressed as Qr=A∈₁σ(T₁⁴−T₂⁴), where Qr is the net radiation power (W), A is the total radiating area (m²), ∈₁ is the emissivity of the object (∈₁=1 for ideal radiator), and σ is the Stefan-Boltzmann constant (5.676×10⁻⁸ W/m²K⁴).

From the above equation, it is found that the net radiation power is a function of the emissivity of the heat sinks 132 and 25. Typically, the heat sinks 132 and 25 are made of aluminum or aluminum alloy, which has an emissivity ∈₁ of about 0.05. This low emissivity contributes to a low net radiation power. That is to say, even though the heat sink 132 or 25 has high thermal conductivity to conduct heat from the electronic component 131 or 22, the efficacy of radiating heat from the surface of the heat sink 132 or 25 to the ambient air via natural convection is unsatisfactory. Likewise, since the electronic components 23 and 24 which are separated from the heat sink 25 have small emissivity, the efficacy of radiating heat from the surface of the electronic component 23 or 24 to the ambient air via natural convection is still unsatisfactory. Since the net radiation power of the heat-dissipating mechanism of the power adapter or power supply apparatus is insufficient, the heat-dissipating efficiency and the temperature drop are limited.

In views of the above-described disadvantages resulted from the prior art, the applicant keeps on carving unflaggingly to develop an electronic device having a passive heat-dissipating mechanism in order to enhance the heat-dissipating efficiency and temperature drop of the electronic device.

### SUMMARY OF THE INVENTION

It is an object of the present invention to provide an electronic device having a passive heat-dissipating mechanism for increasing the heat-dissipating efficiency and temperature drop of the electronic device.

Another object of the present invention provides an electronic device having a passive heat-dissipating mechanism for enhancing the efficacy of radiating heat to the ambient air via natural convection in a simple and cost-effective manner.

In accordance with an aspect of the present invention, there is provided an electronic device having a passive heat-dissipating mechanism. The electronic device includes a circuit board and a radiation enhancement layer. The circuit board has at least an electronic component thereon. The radiation enhancement layer is attached onto at least a portion of a surface of the electronic component for facilitating radiating the heat from the electronic component to the ambient air via natural convection. The radiation enhancement layer is made of a least a ceramic material.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view of a conventional power adapter having a passive heat-dissipating mechanism;

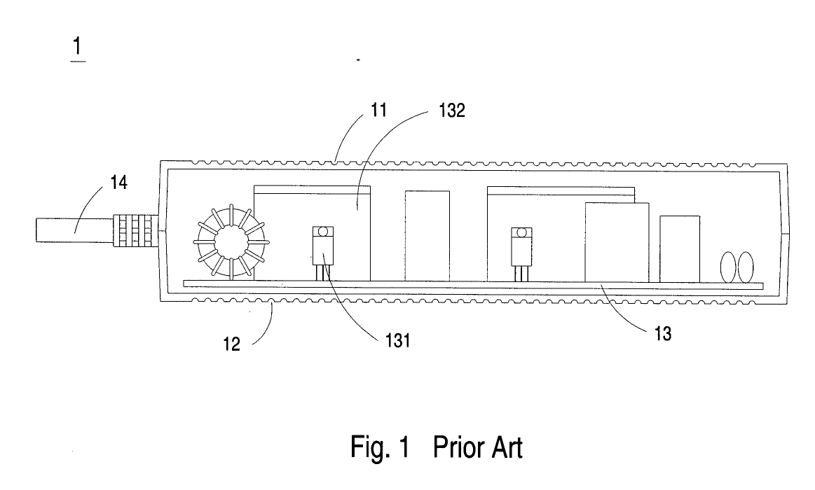

FIG. 2 is a schematic cross-sectional view of a heat-dissipating mechanism for removing the heat generated from the electronic components via natural convection according to prior art;

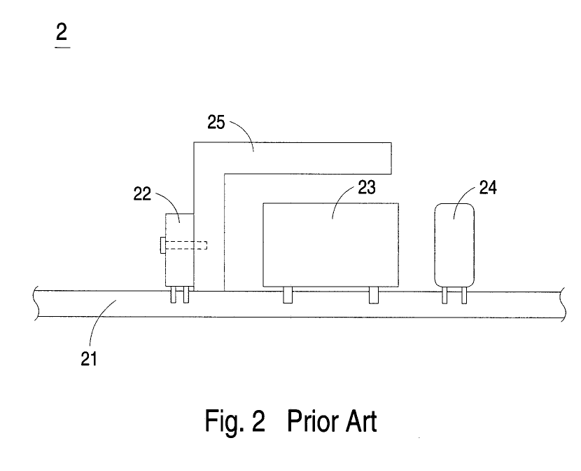

FIG. 3 is a schematic cross-sectional view of an electronic device having a passive heat-dissipating mechanism according to a preferred embodiment of the present invention; and

FIG. 4 is a schematic cross-sectional view of an electronic device having a passive heat-dissipating mechanism according to another preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

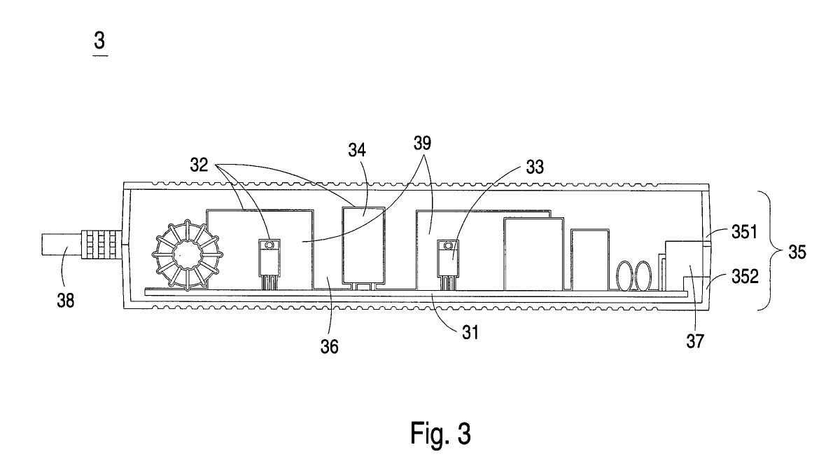

Referring to FIG. 3, a schematic cross-sectional view of an electronic device having a passive heat-dissipating mechanism according to a preferred embodiment of the present invention is illustrated. The electronic device 3 is for example a power supply apparatus or a power adapter. The power adapter 3 principally comprises a circuit board 31 and a radiation enhancement layer 32.

Several electronic components 33 and 34 such as transistors, resistors, capacitors or magnetic elements and electrical trace patterns (not shown) are mounted on the circuit board 31. By the electronic components 33, 34 and the electrical trace patterns, an input voltage from the external power source is converted into a regulated DC output voltage for powering an electronic product. The radiation enhancement layer 32 is at least partially attached on the surfaces of the electronic components 33 and 34. The radiation enhancement layer 32 is made of at least a ceramic material. The radiation enhancement layer 32 may facilitate radiating heat generated from the electronic components 33 and 34 to the ambient air via natural convection.

Examples of the ceramic material used in the radiation enhancement layer 32 include but are not limited to nitrides, oxides, carbides, borides and a combination thereof. Typically, the ceramic material has excellent insulating property, high chemical stability, high thermal conductivity and high emissivity. In addition, the dielectric effect of the ceramic material remains exceptionally strong even at much higher temperature without generating toxic gases or substances. Preferably, the ceramic material is selected from a group consisting of boron nitride, silicon nitride, titanium nitride, aluminum oxide and a combination thereof. Take boron nitride as the ceramic material for example. The boron nitride has a safety operating temperature of 950˜1000° C., a dielectric breakdown voltage of 30˜40 kV/mm, a dielectric constant of 3.9˜5.3∈, a thermal conductivity of about 300 w/mk, and an emissivity of about 0.8. The boron nitride has excellent chemical stability without generating toxic gases or substances at high temperature.

In some embodiments, the radiation enhancement layer 32 are formed on the surfaces of the electronic components 33 and 34, which are mounted on the circuit board 31, by a spraying, dip or coating process. For example, by spraying a solution or a spray agent of the ceramic material dissolved in a solvent (e.g. a ketone such as acetone), the radiation enhancement layer 32 is applied onto the surfaces of the electronic components 33 and 34. Due to the high emissivity of the radiation enhancement layer 32, the efficacy of radiating heat to the ambient air via natural convection will be increased.

In some embodiments, the whole surface of the circuit board 31 is covered by the radiation enhancement layer 32. Moreover, the radiation enhancement layer 32 is uniformly formed on the electronic components 33 and 34. Since the area of the radiation enhancement layer 32 is increased, the efficacy of radiating heat to the ambient air via natural convection will be further increased.

In some embodiments, the electronic device 3 further includes a housing structure 35. The housing structure 35 includes an upper housing 351 and a lower housing 352. A receptacle 36 is defined between the upper housing 3511 and the lower housing 352 for accommodating the printed circuit board 31 therein. Furthermore, the electronic device 3 includes a power input member 37 and a power output member 38. The power input member 37 is for example a power socket. The power output member 38 is for example a power cable.

In order to remove most heat, the electronic device 3 further includes at least a heat sink 39. The heat sink 39 is mounted on the circuit board 31. The electronic components 33 and 34 are contacted with or separated from the heat sink 39. For example, as shown in FIG. 3, the electronic component 33 is screwed onto the heat sink 39, but the electronic component 34 is separated from the heat sink 39. The heat sink 39 may facilitate heat dissipation of the electronic component 33.

Please refer to FIG. 3 again. The heat generated from the electronic component 34 will be conducted to the radiation enhancement layer 32, spread over the surface of the radiation enhancement layer 32, and radiated from the surface of the radiation enhancement layer 32 to the ambient air via natural convection. By means of the passive heat-dissipating mechanism without the use of a fan, the heat will be transferred to the housing structure 35 via natural convection and radiation.

If a hot object at a temperature T₁ (K) is radiating energy to its cooler ambient air at temperature T₂ (K), the Stefan-Boltzmann equation is expressed as Qr=A∈₂σ(T₁⁴−T₂⁴), where Qr is the net radiation power (W), A is the total radiating area (m²), ∈₂ is the emissivity of the object, σ is the Stefan-Boltzmann constant (5.676×10⁻⁸ W/m²K⁴). According to the Stefan-Boltzmann equation described above, the net radiation power is proportioned to the emissivity of the hot object under the same conditions (i.e. the total radiating area A, and the temperatures T₁ and T₂ are identical). In an embodiment, the radiation enhancement layer 32 has an emissivity (∈₂≈0.8) of much greater than the electronic component 34 (∈₂≈0.1). Since the radiation enhancement layer 32 is attached onto the surface of the electronic component 34, the efficacy of radiating heat of the electronic component 34 to the ambient air will be increased. When compared with the conventional passive heat-dissipating mechanism, the working temperature of electronic component 34 is further reduced by 2 to 10° C. by using the passive heat-dissipating mechanism of the present invention. In addition, the working temperature of electronic component around the electronic component 34 is also reduced.

Please refer to FIG. 3 again. In some embodiment, the radiation enhancement layer 32 is attached on a portion of the surface of the heat sink 39. The electronic component 33 is screwed onto the heat sink 39. Likewise, the heat generated from the electronic component 33 will be conducted to the heat sink 39, spread over the surface of the heat sink 39, conducted to the radiation enhancement layer 32, and radiated from the surface of the radiation enhancement layer 32 to the ambient air via natural convection. By means of the passive heat-dissipating mechanism without the use of a fan, the heat will be transferred to the housing structure 35 via natural convection and radiation.

If a hot object at a temperature T₁ (K) is radiating energy to its cooler ambient air at temperature T₂ (K), the Stefan-Boltzmann equation is expressed as Qr=δ₂σ(T₁⁴−T₂⁴), where Qr is the net radiation power (W), A is the total radiating area (m²), ∈₂ is the emissivity of the object, σ is the Stefan-Boltzmann constant (5.676×10⁻⁸ W/m²K⁴). According to the Stefan-Boltzmann equation described above, the net radiation power is proportioned to the emissivity of the hot object under the same conditions (i.e. the total radiating area A, and the temperatures T₁ and T₂ are identical). The heat sink 39 is made of aluminum or aluminum alloy, which has an emissivity ∈₂ of about 0.05. Since the radiation enhancement layer 32 is attached onto the surface of the heat sink 39, the efficacy of radiating heat of the heat sink 39 to the ambient air will be increased.

On the other hand, since the heat sink 39 has high thermal conductivity, the heat generated from the electronic component 33 may be quickly conducted to the surface of the heat sink 39 with a homogenous temperature distribution. Even though the heat sink 39 has low emissivity per se, the radiation enhancement layer 32 attached on the surface of the heat sink 39 may enhance the efficacy of radiating heat of the heat sink 39 to the ambient air.

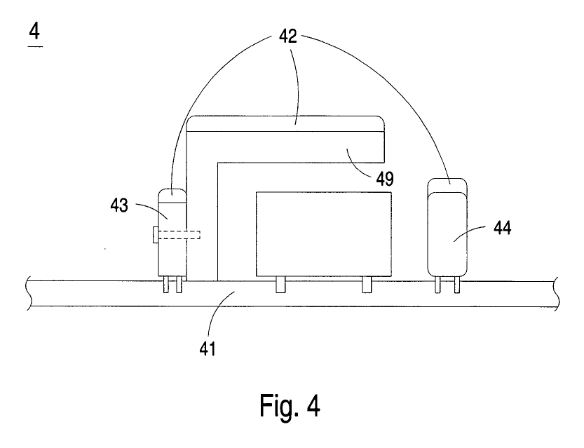

Referring to FIG. 4, a schematic cross-sectional view of an electronic device having a passive heat-dissipating mechanism according to another preferred embodiment of the present invention is illustrated. The electronic device 4 is for example applied to a power supply apparatus of a liquid crystal display. The power adapter 4 principally comprises a circuit board 41 and a radiation enhancement layer 42. As shown in FIG. 4, several electronic components 43 and 44 such as transistors, resistors, capacitors or magnetic elements and electrical trace patterns (not shown) are mounted on the circuit board 41. By the electronic components 43, 44 and the electrical trace patterns, an input voltage from the external power source is converted into a regulated DC output voltage for powering an electronic product. The radiation enhancement layer 42 is at least partially attached on the surfaces of the electronic components 43 and 44. The radiation enhancement layer 42 is made of ceramic material. The radiation enhancement layer 42 may facilitate radiating heat generated from the electronic components 43 and 44 to the ambient air via natural convection.

In order to remove most heat, the electronic device 4 further includes at least a heat sink 49. The heat sink 49 is mounted on the circuit board 41. The electronic components 43 and 44 are contacted with or separated from the heat sink 49. For example, as shown in FIG. 4, the electronic component 43 is screwed onto the heat sink 49, but the electronic component 44 is separated from the heat sink 49. The heat sink 49 may facilitate heat dissipation of the electronic component 43. In some embodiments, the radiation enhancement layer 42 is attached on a portion of the surface of the heat sink 49. The electronic component 43 is screwed onto the heat sink 49. Likewise, the heat generated from the electronic component 43 will be conducted to the heat sink 49, spread over the surface of the heat sink 49, conducted to the radiation enhancement layer 42, and radiated from the surface of the radiation enhancement layer 42 to the ambient air via natural convection.

From the above description, the passive heat-dissipating mechanism of the present invention is capable of enhancing the efficacy of radiating heat to the ambient air via natural convection as well as the heat-dissipating efficiency. The use of the radiation-enhancing layer to increase the emissivity of the electronic component and/or the heat sink on the circuit board is simpler and more cost-effective when compared with prior art.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An electronic device having a passive heat-dissipating mechanism, comprising:
a circuit board having at least an electronic component thereon; and
a radiation enhancement layer attached onto at least a portion of a surface of said electronic component for facilitating radiating the heat from said electronic component to the ambient air via natural convection, wherein said radiation enhancement layer is made of at least a ceramic material.

2. The electronic device according to claim 1 further including at least a heat sink, which is contacted with or separated from said electronic component.

3. The electronic device according to claim 2 wherein said radiation enhancement layer is attached onto at least a portion of a surface of said heat sink for facilitating radiating the heat from said heat sink to the ambient air via natural convection.

4. The electronic device according to claim 3 wherein said radiation enhancement layer has an emissivity greater than an emissivity of said heat sink.

5. The electronic device according to claim 2 wherein said heat sink is made of a metallic material.

6. The electronic device according to claim 1 wherein said ceramic material is selected from a group consisting of nitride, oxide, carbide, boride and a combination thereof.

7. The electronic device according to claim 6 wherein said ceramic material is selected from a group consisting of boron nitride, silicon nitride, titanium nitride, aluminum oxide and a combination thereof.

8. The electronic device according to claim 1 wherein said radiation enhancement layer has an emissivity greater than an emissivity of said electronic component.

9. The electronic device according to claim 1 wherein said electronic device is a power adapter or a power supply apparatus.

10. The electronic device according to claim 1 further including a housing structure, which includes an upper housing and a lower housing.

11. The electronic device according to claim 10 further including a power input member and a power output member, which are disposed on said housing structure.

12. The electronic device according to claim 1 wherein said radiation enhancement layer is attached onto said electronic component by a spraying, dip or coating process.

13. The electronic device according to claim 12 wherein said radiation enhancement layer is attached onto said electronic component by spraying a solution or a spray agent of said ceramic material dissolved in a solvent.

14. The electronic device according to claim 13 wherein said solvent is acetone.
